(19) United States
(12) Patent Application Publication
(10) Pub. No.: US 2013/0032083 A1
(43) Pub. Date: Feb. 7, 2013

(54) SINGLE-CRYSTAL MANUFACTURING APPARATUS AND METHOD FOR MANUFACTURING SINGLE CRYSTAL

(71) Applicants: Katsuyuki Kitagawa, Echizen (JP); Atsushi Iwasaki, Echizen (JP); Hiroshi Ohtsuna, Echizen (JP)

(72) Inventors: Katsuyuki Kitagawa, Echizen (JP); Atsushi Iwasaki, Echizen (JP); Hiroshi Ohtsuna, Echizen (JP)

(73) Assignee: SHIN-ETSU HANDOTAI CO., LTD., Tokyo (JP)

(21) Appl. No.: 13/641,999

(22) PCT Filed: Apr. 6, 2011
(86) PCT No.: PCT/JP2011/002030

§ 371 Date: Oct. 18, 2012

(30) Foreign Application Priority Data
May 12, 2010 (JP) 2010-109993

(51) Int. Cl. C30B 15/20; C30B 15/14

(52) U.S. Cl. 117/14; 117/201

(57) ABSTRACT

The present invention provides a single-crystal manufacturing apparatus comprising a chamber that accommodates a crucible containing a raw material melt; a pulling mechanism for pulling a single crystal; a heater for heating the raw material melt, the heater being movable upwardly and downwardly; and a temperature measurement means for measuring temperature of the heater, wherein the temperature measurement means is movable upwardly and downwardly in response to the upward and downward movement of the heater. The present invention provides a single-crystal manufacturing apparatus and a method for manufacturing a single crystal that can stably measure the heater temperature regardless of a change in operation conditions and hence stably control the heater temperature and the heater output, resulting in a stable operation.

### TECHNICAL FIELD

The present invention relates to a single-crystal manufacturing apparatus and a method for manufacturing a single crystal that enable the temperature of a heater to be stably measured when the single crystal is pulled.

### BACKGROUND ART

One of methods used in manufacture of a silicon single crystal, which is a substrate material for use in a semiconductor integrated circuit or the like, is the Czochralski method (also referred to as the CZ method) in which a cylindrical single crystal is pulled from a raw material melt in a crucible.

In the CZ method, a polycrystalline raw material is charged into a crucible 23 provided at the interior of a chamber 21 of a single-crystal manufacturing apparatus, for example, shown in FIG. 4, and the raw material is heated and melted with a cylindrical heater (an heat insulating cylinder 25 is also provided around the outer circumferential portion of the heater) provided around the outer circumferential portion of the crucible 23. A seed crystal attached to a seed chuck is then dipped into the melt and while the seed chuck and the crucible 23 are rotated in the same direction or opposite direction, the seed chuck is pulled to grow the single crystal.

In the manufacture of a single crystal according to the CZ method, the temperature of the heater 22 is measured with a thermometer (a temperature measurement means 24), such as a radiation thermometer, fixed to the chamber 21 and the like to control the temperature of the heater 22 (See Patent Documents 1 and 2, for example).

### CITATION LIST

### Patent Literature

Patent Document 1: Japanese Unexamined Patent publication (Kokai) No. H05-24967

Patent Document 2: Japanese Unexamined Patent publication (Kokai) No. H03-137092

### SUMMARY OF INVENTION

A graphite heater commonly used in the manufacture of a single crystal according to the CZ method is of a slit-type.

The heater, however, has different current densities between near the ends of slits and near its center (the center of heat generator); therefore, to be precise, the measured temperature varies depending on a measurement position.

The temperature measurement means 24 is generally fixed to the chamber 21 or the like. Therefore, there has been a problem in that, when the position of the heater varies vertically by operation conditions, for example, by raising the heater 22 as the crucible 23 rises, the position of the temperature measurement varies.

Accordingly, when the position of the heater varies due to a change in operation conditions, the measured temperature varies according to the variation in the position of the temperature measurement even though an actual temperature of the heater is not changed.

Since the output of the heater is adjusted on the basis of the measured temperature of the heater, the variation in the measured temperature of the heater causes the heater power to change. There have therefore been problems in that the actual temperature of the heater exceeds a predetermined control temperature and the output of the heater does not stabilized.

The present invention was accomplished in view of the above-described problems. It is an object of the present invention to provide a single-crystal manufacturing apparatus and a method for manufacturing a single crystal that can stably measure the heater temperature regardless of a change in operation conditions and hence stably control the heater temperature and the heater output, resulting in a stable operation.

To achieve this object, the present invention provides a single-crystal manufacturing apparatus including a chamber that accommodates a crucible containing a raw material melt; a pulling mechanism for pulling a single crystal; a heater for heating the raw material melt, the heater being movable upwardly and downwardly; and a temperature measurement means for measuring temperature of the heater, wherein the temperature measurement means is movable upwardly and downwardly in response to the upward and downward movement of the heater.

The temperature measurement means movable upwardly and downwardly in response to the upward and downward movement of the heater can always measure the heater temperature at the same position, preventing measurement error due to the variation in the measurement position of the heater temperature. Therefore, the single-crystal manufacturing apparatus can stably measure the temperature of the heater and stabilize the heater output, enabling a stable operation.

The temperature measurement means preferably includes: a radiation thermometer; a shaft for moving the radiation thermometer upwardly and downwardly; a driving motor for driving the shaft; and a motor driver that actuates the driving motor.

With such a temperature measurement means, the radiation thermometer, which can stably measure the temperature of the heater heated to a high temperature, can be upwardly and downwardly moved stably with high precision in response to the upward and downward movement of the heater, the temperature of the heater can be more stably measured, and the output of the heater can be more stabilized.

The single-crystal manufacturing apparatus preferably includes a heat insulating cylinder disposed around an outer circumferential portion of the heater, and it is preferable that the heat insulating cylinder and the chamber are each provided with a temperature measurement hole for use in measuring the temperature of the heater and the temperature measurement hole is an elongated hole.

When the heat insulating cylinder disposed around the outer circumferential portion of the heater and the chamber are each provided with the temperature measurement hole having an elongated hole shape, the temperature of the heater can be more easily and stably measured through the elongated hole in response to the upward and downward movement of the heater, and the apparatus can be more stably operated.

Furthermore, the present invention provides a method for manufacturing a single crystal according to the Czochralski method, including pulling the single crystal with a pulling mechanism from a raw material melt contained in a crucible, the raw material melt being melted by a heater, in which the single crystal is pulled while a temperature measurement means for measuring temperature of the heater is moved upwardly and downwardly in response to upward and downward movement of the heater.

When the single crystal is pulled while the temperature measurement means for measuring temperature of the heater is moved upwardly and downwardly in response to upward and downward movement of the heater, the measurement position of the heater temperature can be fixed to a certain position on the heater, and the temperature of the heater can be stably measured. Therefore, the output of the heater can be stabilized when the single crystal is pulled, and consequently the single crystal can stably be pulled.

In the method, the height position at which the temperature of the heater is measured with the temperature measurement means preferably falls within the range of ±10 mm from a center of the heater.

Current density at the range of ±10 mm from the center of the heater stabilizes more than that at other positions (e.g., the end of the slits) and its temperature thus stabilizes. Therefore, when the height position at which the temperature of the heater is measured with the temperature measurement means falls within the range of ±10 mm from the center of the heater, the single crystal can be pulled while the temperature is measured at the height position at which the heater temperature stabilizes, the output of the heater can be stably controlled, and a stable operation can be achieved.

As described above, by moving the temperature measurement means upwardly and downwardly in response to the upward and downward movement of the heater according to the present invention, the temperature measurement means can be kept at the same height position as that of the heater; thereby the temperature variation and even an effect of temperature variation caused by a split-type graphite crucible can be inhibited with higher precision; consequently the heater temperature control can be considerably stabilized in comparison with that in the past. The diameter of the single crystal can therefore be readily controlled during manufacturing, generation of dislocation in a grown crystal can consequently be reduced, and productivity can be improved. Moreover, stable temperature measurement stabilizes a pulling rate of the crystal, and a single crystal having a desired crystal quality can be stably obtained more than in the past. The present invention provides a single-crystal manufacturing apparatus and a method for manufacturing a single crystal enabling these effects.

### BRIEF DESCRIPTION OF DRAWINGS

FIG. 1 is a schematic view showing an example of the single-crystal manufacturing apparatus of the present invention;

FIG. 2 is an outline view enlarging the shape of a common heater near its electrode;

FIG. 3 shows the relationship between the measurement position of the heater temperature and a maximum variation in the output (electric power) of the heater in Examples 1 and 2; and

FIG. 4 is a schematic view showing an example of a conventional single-crystal manufacturing apparatus.

### DESCRIPTION OF EMBODIMENTS

Hereinafter, the present invention will be described in detail with reference to the drawings, but the present invention is not limited thereto.

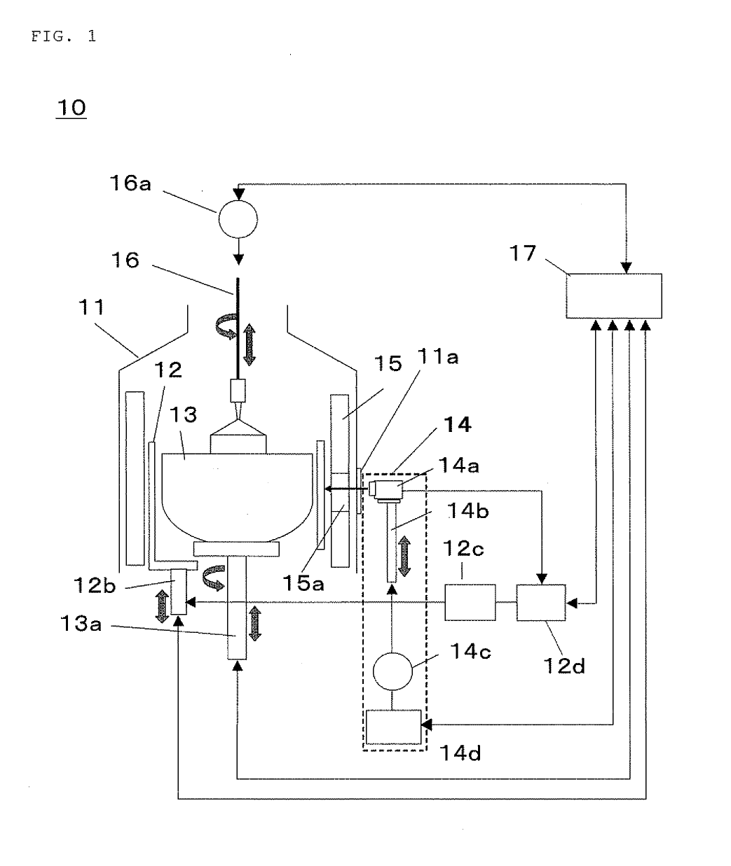

As illustrated in FIG. 1, the single-crystal manufacturing apparatus 10 of the present invention includes the chamber 11 that accommodates the crucible 13 containing a raw material melt, the pulling mechanism 16 for pulling a single crystal, the upwardly and downwardly movable heater 12 for heating the raw material melt, the temperature measurement means 14 for measuring the temperature of the heater 12, and the heat insulating cylinder 15 disposed around the outer circumferential portion of the heater 12.

The temperature measurement means 14 is not fixed to a chamber body but movable upwardly and downwardly in response to the upward and downward movement of the heater 12, so that its measurement position can be varied. For example, as shown in FIG. 1, the temperature measurement means 14 includes the radiation thermometer 14a, the shaft 14b for moving the radiation thermometer upwardly and downwardly, the driving motor 14c for driving the shaft, and the motor driver 14d that actuates the driving motor 14c.

In the temperature measurement means 14 configured as above, the position at which the radiation thermometer 14a measures the heat temperature is adjusted, in advance, to near the center of the heater 12, for example, and the adjusted position is set as a reference position. The same commands of upward and downward movement as that to be given to the heater shaft 12b are given to the motor driver 14d of the shaft 14b for moving the radiation thermometer upwardly and downwardly, and the shaft 14b for moving the radiation thermometer upwardly and downwardly is moved upwardly and downwardly with the driving motor 14c so that the radiation thermometer 14a and the heater shaft 12b are linked in terms of the upward and downward movement.

As a result, the movement of the radiation thermometer 14a is linked to that of the heater 12, and the radiation thermometer 14a can always measure the temperature near the center of the heater 12.

Feedback about the temperature of the heater 12 measured with the radiation thermometer 14a is given to a temperature regulator 12d for adjusting the heater temperature. The temperature regulator 12d sends signals to a heater power source 12c on the basis of feedback signals to adjust the output (electric power) of the heater 12.

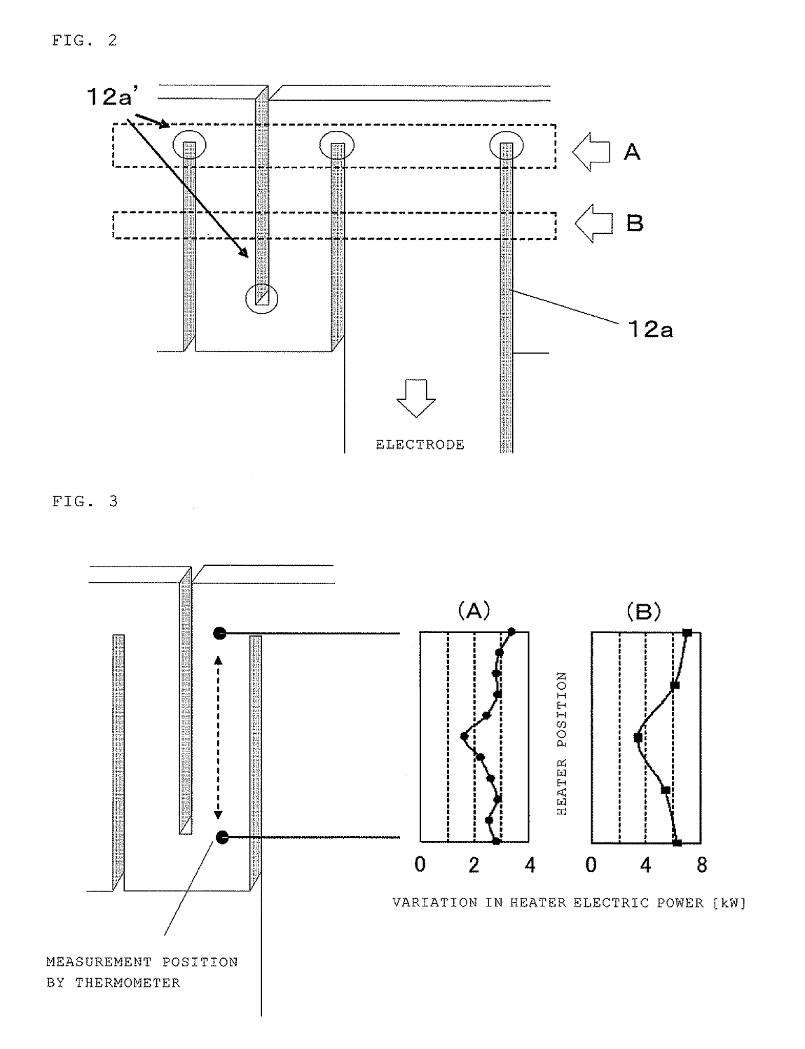

As shown in FIG. 2, in a commonly used heater having formed slits 12a, variation in heater electric power near heater slit ends 12a′ (region A), which has larger current density, is larger during the temperature control. On the other hand, the heater electric power stabilizes at the center of the heater (region B). Therefore, when the measurement position of the heater temperature changes, the measured temperature conventionally differs from an actual temperature even though the actual temperature is not changed.

According to the single-crystal manufacturing apparatus of the present invention, however, moving the temperature measurement means for measuring the heater temperature upwardly and downwardly in response to the upward and downward movement of the heater prevents the measurement position of the heater temperature from changing when the single crystal is pulled, thereby enabling the heater temperature to be measured continually at the same position. Therefore, the heater temperature can be stably measured and the output of the heater controlled on the basis of the measured heater temperature can be stabilized. As a result of these effects, the single crystal can be stably pulled and the state of the raw material melt and the crystal quality of the pulled single crystal can be also stabilized.

Here, driving parts (e.g., motor drivers that each actuates heater shaft 12b, crucible shaft 13a, shaft 14b for moving the radiation thermometer upwardly and downwardly, and motor 16a for moving a pulling shaft upwardly and downwardly) of the single-crystal manufacturing apparatus 10 are operable in response to commands (a position, rotational speed, and direction) sent from a computer 17 for control to each of the motor drivers.

The motor drivers each gives feedback about its current status (a position, rotational speed, and direction) of driving at the corresponding driving part to the computer 17 to control them to achieve target values.

The temperature measurement means 14 is not limited to the embodiment illustrated in FIG. 1 as long as it is capable of moving upwardly and downwardly in response to the upward and downward movement of the heater 12. For example, a resistance temperature detector can be used as the temperature measurement means 14.

The height position at which the temperature of the heater 12 is measured with the temperature measurement means 14 preferably falls within the range of ±10 mm from the center of the heater 12.

As shown in FIG. 1, the chamber 11 and the heat insulating cylinder 15 disposed around the outer circumferential portion of the heater 12 can be provided with the temperature measurement holes 11a and 15a for use in measuring the temperature of the heater 12, respectively. The temperature measurement holes 11a and 15a can each be an elongated hole.

The temperature measurement holes of elongated holes provided at the chamber and the heat insulating cylinder disposed around the outer circumferential portion of the heater enable a distance of the heater movement during its operation to be taken into account to surely prevent the lack of a measurable range of a thermometer such as the radiation thermometer. The temperature of the heater can therefore be measured surely and stably while the heater moves upwardly and downwardly; thereby a stable operation can be achieved.

An embodiment of the method for manufacturing a single crystal of the present invention with the above-described single-crystal manufacturing apparatus of the present invention will be described below. The present invention, however, is not limited to this embodiment.

When the single crystal is pulled from the raw material melt in the crucible 13 of the single-crystal manufacturing apparatus 10, the heater 12 disposed around the crucible 13 needs to heat a raw material in the crucible 13 to melt it.

When the heater 12 heats the raw material, voltage is applied to the heater 12 to turn on the electricity; therebetween the temperature of the heater 12 is measured with the temperature measurement means 14 such as the radiation thermometer 14a to indirectly evaluate the temperature of the crucible 13 and the raw material melt naturally.

A seed crystal is dipped into the raw material melt in the crucible 13 and the single crystal is then pulled from the raw material melt. The crucible 13 is movable in the direction of a crystal growth axis. The crucible 13 is moved upwardly during growth of the single crystal to compensate the decreasing surface level of the raw material melt as the single crystal is grown so that the surface of the raw material melt is always held at a constant height.

The heater 12 also moves upwardly and downwardly in response to the movement of the crucible. In the present invention, the single crystal is pulled while the temperature measurement means 14 for measuring temperature of the heater 12, in addition to the heater 12, is moved upwardly and downwardly in response to the upward and downward movement of the heater 12, unlike conventional methods.

As described above, pulling the single crystal while the temperature measurement means for measuring the heater temperature is moved upwardly and downwardly in response to the upward and downward movement of the heater can prevent the measurement position of the heater temperature from changing with respect to the position of the hater, enabling the heater temperature to be measured continually at the same position.

The heater temperature can therefore be stably measured more than in the past and the heater output also stabilizes when the single crystal is pulled. The heater output controlled on the basis of the measured temperature and an actual temperature of the heater can therefore stabilize. The convection of the raw material melt and the quality of the single crystal being pulled can also stabilize.

In the method, the height position at which the temperature of the heater is measured with the temperature measurement means can be set to within the range of ±10 mm from the center of the heater.

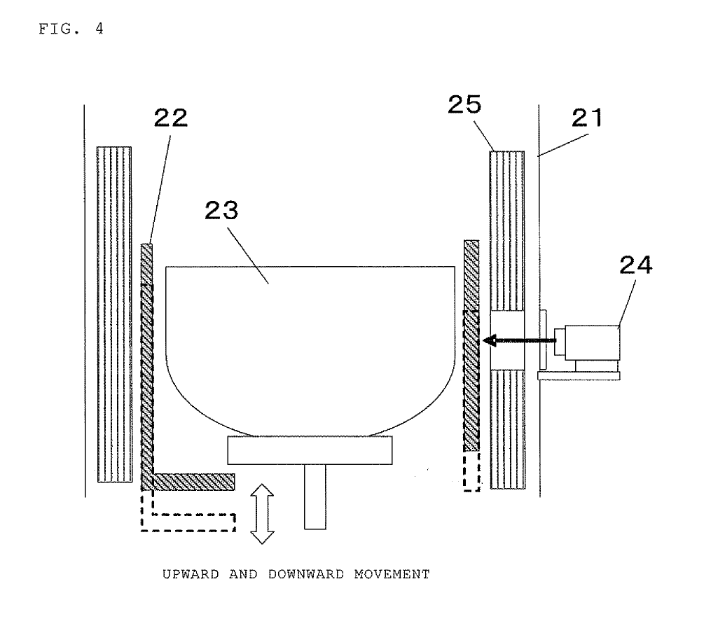

When the temperatures practically measured with the radiation thermometer near the heater slit end (region A) and near the center of the heater (region B) are compared in the heater during growth of the single crystal, the variation in heater electric power near the heater slit end, which has larger current density, is larger when the temperature is controlled (See FIGS. 2 and 3). This variation can be extra factors in disturbance in temperature control. In view of this, when the measurement position of the heater temperature falls within the range of ±10 mm from the center of the heater where variation in temperature in circumferential direction of the heater is low, the single crystal can be pulled while the heater temperature is always measured at a position at which the heater temperature stabilizes, and more stable control of the heater output and a stable operation can be realized.

### EXAMPLE

The present invention will be more specifically described below with reference to Examples, but the present invention is not limited to these examples.

### Example 1

The relationship between the measurement position of the heater temperature and variation in temperature was confirmed by an empty heating test in which a raw material was not introduced into the crucible. In the test, the radiation thermometer was moved upwardly in response to the upward movement of the heater to measure the heater temperature continually at the same position under conditions of: a furnace structure using a 26 in. diameter (650 mm) crucible; a heater usage time of 400 hours; a heater electric power of 100 kW; and a crucible rotating rate of 0.1 rpm.

The term “variation in temperature” as used herein refers to variation in temperature occurring near a joint of split crucible parts (a crucible rotation period) when a graphite crucible split into two parts is used. The measured heater temperature periodically varies with the rotation of the crucible under the influence of the joint of the crucible; consequently the heater output controlled on the basis of the measured heater temperature also periodically varies with the rotation of the crucible.

As shown in FIG. 3(A), in the cases where the measurement position of the heater temperature was set to both near the heater center and the slit end, the variation in temperature (variation in electric power) when the heater temperature was measured near the heater center was about 50% lower than that when it was measured near the slit end.

When the measurement position of the heater temperature was gradually changed from the vicinity of the slit end toward the center, the variation in temperature similarly decreased as it approached the center.

When the measurement position of the heater temperature fell within the range of ±10 mm from the center of the heater, the variation in temperature was minimized.

In the case of the measurement at the slit end exhibiting maximum temperature variation in Example 1, the heater output variation was about 90% of that in a conventional case in which the thermometer was not moved. The range of the variation was equal to or less than 50% at the center. It was accordingly confirmed that the present invention can more stabilize the heater output at any measurement positions of the heater temperature than in the past.

### Example 2

A next test was carried out to confirm whether similar results were obtained under actual operation conditions. The conditions included as follows: a furnace structure using a 26 in. diameter (650 mm) crucible; a heater usage time of 1200 hours; a heater electric power of 120 kW; a crucible rotating rate of 0.1 rpm; and a period before the seed crystal was dipped.

In Example 2, as shown in FIG. 3(B), the temperature variation was minimized when the measurement position of the heater temperature was the heater center as in Example 1. When the thermometer was not moved, the range of the variation was equal to or more than 8 kW. It was accordingly confirmed that the variation was greatly improved.

As described above, it was confirmed that the heater temperature can be stably measured by moving the radiation thermometer upwardly in response to the upward movement of the heater to measure the temperature continually at the same position according to the present invention.

It was also confirmed that always fixing the measurement position of the heater temperature to approximately ±10 mm from the center of the heater reduces the influence of disturbance and more stabilizes the temperature measurement.

It is to be noted that the present invention is not limited to the foregoing embodiment. The embodiment is just an exemplification, and any examples that have substantially the same feature and demonstrate the same functions and effects as those in the technical concept described in claims of the present invention are included in the technical scope of the present invention.

1-5. (canceled)

6. A single-crystal manufacturing apparatus comprising
a chamber that accommodates a crucible containing a raw material melt;
a pulling mechanism for pulling a single crystal;
a heater for heating the raw material melt, the heater being movable upwardly and downwardly; and
a temperature measurement means for measuring temperature of the heater, wherein
the temperature measurement means is movable upwardly and downwardly in response to the upward and downward movement of the heater.

7. The single-crystal manufacturing apparatus according to claim 6, wherein the temperature measurement means includes: a radiation thermometer; a shaft for moving the radiation thermometer upwardly and downwardly; a driving motor for driving the shaft; and a motor driver that actuates the driving motor.

8. The single-crystal manufacturing apparatus according to claim 6, further comprising a heat insulating cylinder disposed around an outer circumferential portion of the heater, wherein the heat insulating cylinder and the chamber are each provided with a temperature measurement hole for use in measuring the temperature of the heater, and the temperature measurement hole is an elongated hole.

9. The single-crystal manufacturing apparatus according to claim 7, further comprising a heat insulating cylinder disposed around an outer circumferential portion of the heater, wherein the heat insulating cylinder and the chamber are each provided with a temperature measurement hole for use in measuring the temperature of the heater, and the temperature measurement hole is an elongated hole.

10. A method for manufacturing a single crystal according to the Czochralski method, the method comprising
pulling the single crystal with a pulling mechanism from a raw material melt contained in a crucible, the raw material melt being melted by a heater, wherein
the single crystal is pulled while a temperature measurement means for measuring temperature of the heater is moved upwardly and downwardly in response to upward and downward movement of the heater.

11. The method for manufacturing a single crystal according to claim 10, wherein a height position at which the temperature of the heater is measured with the temperature measurement means falls within the range of ±10 mm from a center of the heater.
